(19) United States
(12) Patent Application Publication
(10) Pub. No.: US 2021/0068273 A1
(43) Pub. Date: Mar. 4, 2021

(54) DISPLAY DEVICE AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Jun CHEN, Wuhan, Hubei (CN); Liang SUN, Wuhan, Hubei (CN)

(21) Appl. No.: 16/753,810

(22) PCT Filed: Dec. 6, 2019
(86) PCT No.: PCT/CN2019/123468

§ 371 Date: Apr. 6, 2020

(30) Foreign Application Priority Data
Sep. 3, 2019 (CN) 201910826933.9

(51) Int. Cl. H05K 5/00; H05K 5/03

(52) U.S. Cl. CPC H05K 5/0017; H05K 5/03

(57) ABSTRACT

A display device and a manufacturing method are provided. The display device includes a housing and a flexible display screen. The housing is substantially a rectangular parallelopiped and is disposed with a top surface, a bottom surface, and two lateral surfaces. The flexible display screen covers the top surface and the two lateral surfaces of the housing and includes a flexible display panel, a first cover plate, and a second cover plate which are disposed in a stack. The manufacturing method of the display device includes: providing the housing, attaching the flexible display panel, attaching the first cover plate, and attaching the second cover plate.

### FIELD OF INVENTION

The present disclosure relates to the field of display, and particularly relates to a display device and a manufacturing method thereof.

### BACKGROUND OF INVENTION

With continuous development of display technology and demands of people, mobile electronic devices such as mobile phones, tablet PCs, etc. are increasingly popularized in daily life, and their usages and functions are becoming increasingly versatile and wide-ranging.

In recent years, mobile devices with a high screen-to-body ratio are very popular and have become an inevitable development trend. Compared to mobile devices in the prior arts, mobile devices with a high screen-to-body ratio have advantages such as larger display regions, narrower bezels, smaller dimensions but same screen size, etc. Based on this trend, some industry practitioners have developed mobile devices with curved displays, or mobile devices simultaneously disposed with front main screens and backside sub-screens. Through these means, the screen-to-body ratio of mobile devices can be further increased to enrich user experience for consumers. However, on one hand, these schemes still have large bezels, and on the other hand, two independent screens are used in these schemes, which increases a thickness of the mobile devices.

Therefore, it is necessary to provide a new display device and a manufacturing method thereof to overcome the problem of the prior art.

### SUMMARY OF INVENTION

The purpose of the present disclosure is to provide a display device and a manufacturing method that not only increases a screen-to-body ratio of the display device and realizes thinness, but also ensures a surface of the flexible display panel to have a certain hardness and flatness.

In order to realize the purpose mentioned above, one embodiment of the present disclosure provides a display device includes a housing and a flexible display screen. The housing is substantially a rectangular parallelopiped and is disposed with a top surface, a bottom surface, and two lateral surfaces. The flexible display screen covers the top surface and the two lateral surfaces of the housing and includes a flexible display panel, a first cover plate, and a second cover plate which are disposed layer by layer. Specifically, the first cover plate is disposed on the flexible display panel, and the second cover plate is disposed on the first cover plate.

Furthermore, the lateral surfaces include a left side surface and a right side surface, and the flexible display screen covers the left side surface and/or the right side surface of the housing.

Furthermore, the flexible display screen covers the bottom surface of the housing.

Furthermore, the flexible display screen completely covers the bottom surface of the housing.

Furthermore, any one of the top surface, the bottom surface, or the lateral surfaces is set to be arc surface.

Furthermore, at least one of the first cover plate or the second cover plate is a glass film with a thickness less than or equal to 150 μm to ensure a flatness and a surface hardness of the flexible display screen, and a tactile sense of the flexible display screen is consistent with a mobile device in prior art.

Furthermore, a material of the first cover plate or the second cover plate includes transparent polyimide.

Furthermore, the display device further includes a third cover plate, and the third cover plate is disposed on the second cover plate.

One embodiment of the present disclosure further provides a manufacturing method of a display device, which includes following steps:

A step of providining a housing, which is providing a housing, wherein the housing is substantially a rectangular parallelopiped and is disposed with a top surface, a bottom surface, and two lateral surfaces.

A step of attaching a flexible display panel, which is attaching a flexible display panel on the top surface of the housing, and then attaching a lateral side of the flexible display screen on lateral surfaces of the housing.

A step of attaching a first cover plate, which is attaching a first cover plate on the top surface of the housing, and then attaching a lateral side of the first cover plate on the flexible display panel located on the lateral surfaces of the housing.

A step of attaching a second cover plate, which is attaching a second cover plate on the top surface of the housing, and then attaching a lateral side of the second cover plate on the first cover plate located on the lateral surfaces of the housing.

Furthermore, the step of attaching the flexible display panel further includes: attaching the flexible display panel on the bottom surface of the housing; the step of attaching the first cover plate further includes: attaching the first cover plate on the flexible display panel located on the bottom surface of the housing; and the step of attaching the second cover plate further includes: attaching the second cover plate on the first cover plate located on the bottom surface of the housing.

The beneficial effect of the present disclosure is: a display device and a manufacturing method thereof are provided. Through covering the top surface, the bottom surface, and the lateral surfaces of the housing by using one whole flexible display panel, this not only increases a screen-to-body ratio of the display device and realizes thinness, but also ensures that a surface of the flexible display panel has a certain hardness and flatness.

### DESCRIPTION OF DRAWINGS

FIG. 1 is a structural schematic diagram of a whole display device in a first embodiment.

FIG. 2 is a sectional diagram extending along an A-A section in FIG. 1, displaying a structural schematic diagram of a flexible display screen covering a top surface and a left side surface of a housing in the first embodiment.

FIG. 3 is a sectional diagram extending along the A-A section in FIG. 1, displaying a structural schematic diagram of the flexible display screen covering the top surface and a right side surface of the housing in the first embodiment.

FIG. 4 is a sectional diagram extending along the A-A section in FIG. 1, displaying a structural schematic diagram of the flexible display screen covering the top surface, the left side surface, and the right side surface of the housing in the first embodiment.

FIG. 5 is a flowchart of a manufacturing method of the display device in the first embodiment.

FIG. 6A is a structural schematic diagram of a display device in a second embodiment.

FIG. 6B is another structural schematic diagram of the display device in a second embodiment.

FIG. 7 is a sectional diagram of a flexible display screen covering a top surface, a left side surface, and a right side surface of a housing, and partially covering a bottom surface of the housing in the second embodiment.

FIG. 8A is a sectional diagram of the flexible display screen completely covering the top surface, the left side surface, the right side surface, and the bottom surface of the housing in the second embodiment.

FIG. 8B is a sectional diagram of the flexible display screen completely covering the top surface, the bottom surface, and the left side surface or the right side surface of the housing in the second embodiment.

### DETAILED DESCRIPTION OF PREFERRED EMBODIMENTS

In the description of the present disclosure, it is to be understood that the orientation or positional relationship indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise” etc. is based on the orientation or positional relationship shown in the accompanying figures, which is merely for the convenience for describing of the present disclosure and for the simplification of the description, and is not intended to indicate or imply that the indicated devices or elements have a specific orientation or is constructed and operated in a specific orientation. Therefore, it should not be understood as a limitation on the present disclosure. Moreover, the terms “first” and “second” are used for descriptive purposes only and are not to be understood as indicating or implying relative importance or implicitly indicating the number of the indicated technical characteristics. Therefore, the characteristics defined by “first” or “second” may include one or more of the described characteristics either explicitly or implicitly. In the description of the present disclosure, the meaning of “a plurality” is two or more unless clearly and specifically defined otherwise.

In the present disclosure, unless expressly specified or limited otherwise, a first feature is “on” or “beneath” a second feature may include that the first feature directly contacts the second feature and may also include that the first feature does not directly contact the second feature. Furthermore, a first feature “on,” “above,” or “on top of” a second feature may include an embodiment in which the first feature is right “on,” “above,” or “on top of” the second feature and may also include that the first feature is not right “on,” “above,” or “on top of” the second feature, or just means that the first feature has a sea level elevation higher than the sea level elevation of the second feature. While first feature “beneath,” “below,” or “on bottom of” a second feature may include that the first feature is “beneath,” “below,” or “on bottom of” the second feature and may also include that the first feature is not right “beneath,” “below,” or “on bottom of” the second feature, or just means that the first feature has a sea level elevation lower than the sea level elevation of the second feature.

### First Embodiment

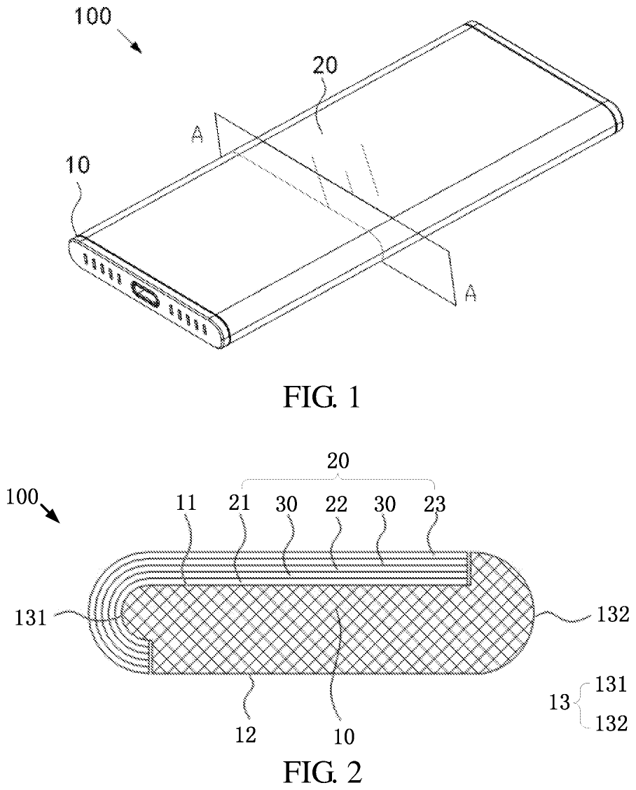

Please refer to FIG. 1, a first embodiment of the present disclosure provides a display device 100, which includes a housing 10 and a flexible display screen 20. The flexible display screen 20 acts as a display region of the display device 100.

Please refer to FIG. 2 to FIG. 4, which are sectional diagrams at an A-A position in FIG. 1. The housing 10 is substantially a rectangular parallelopiped and is disposed with a top surface 11, a bottom surface 12, and two lateral surfaces 13. The flexible display screen 20 covers the top surface 11 and the two lateral surfaces 13 of the housing 10. The flexible display screen 20 includes a flexible display panel 21, a first cover plate 22, and a second cover plate 23, which are disposed in a stack. Specifically, the first cover plate 22 is disposed on the flexible display panel 21, and the second cover plate 23 is disposed on the first cover plate 22. Furthermore, the flexible display panel 21, the first cover plate 22, and the second cover plate 23 are connected to each other by an optically clear adhesive 30.

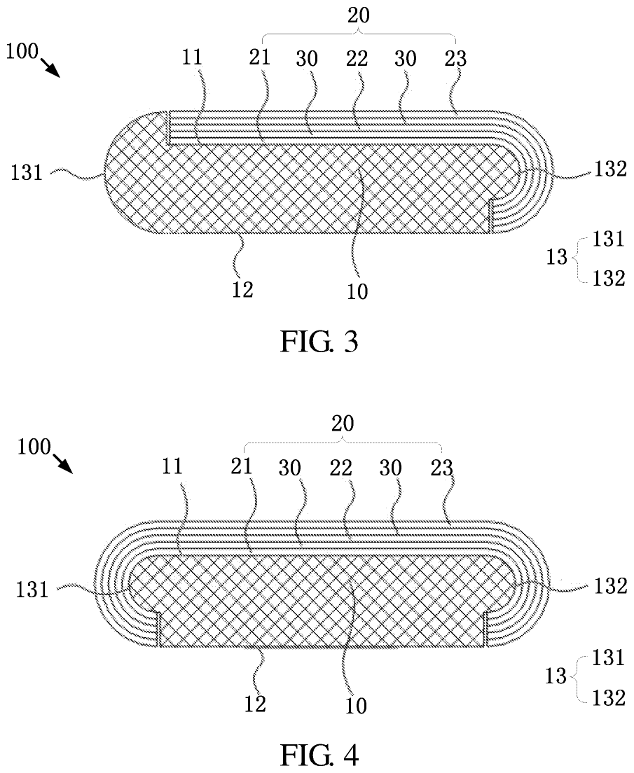

In this embodiment, the lateral surfaces 13 include a left side surface and 131 a right side surface 132, and the flexible display screen 20 covers the left side surface 131 and/or the right side surface 132 of the housing 10, and at this time, there is no display region on the bottom surface 12. In FIG. 2, the flexible display screen 20 covers the left side surface 131 of the housing 10. In FIG. 3, the flexible display screen 20 covers the right side surface 132 of the housing 10. In FIG. 4, the flexible display screen 20 covers the left side surface 131 and the right side surface 132 of the housing 10.

In this embodiment, any one of the top surface 11, the bottom surface 12, or the lateral surfaces 13 is set as an arc surface, that is, one or a more of the top surface 11, the bottom surface 12, and the lateral surfaces 13 can be set as an arc surface, so that an appearance is smooth and a problem of poor display in wide viewing angles can be solved.

In this embodiment, at least one of the first cover plate 22 or the second cover plate 23 is a glass film with a thickness less than or equal to 150 μm. The glass film can ensure flatness and surface hardness of the flexible display screen 20, while tactile sense of the flexible display screen 20 is consistent with a mobile device in the prior art.

In this embodiment, a material of the first cover plate 22 or the second cover plate 23 includes transparent polyimide.

In this embodiment, the display device 100 further includes a third cover plate (not show in the figures), and the third cover plate is disposed on the second cover plate 23. A material of the third cover plate includes glass or transparent polyimide. It can be understood that the cover plates of the display device 100 are a multilayer structure. A layer number of the structure is greater than or equal to 2, that is, it at least includes the first cover plate 22 and the second cover plate 23, and at the same time, it can be disposed with more cover plates, such as the third cover plate, to improve hardness.

The display device 100 in this embodiment can be any products or components having display functions, such as wearable devices, mobile phones, tablet PCs, televisions, display devices, laptops, e-books, e-newsletters, digital photo frames, global positioning systems, etc. Furthermore, the wearable devices include smart bracelets, smart watches, virtual reality (VR) devices, etc.

Please refer to FIG. 1 to FIG. 5, one embodiment of the present disclosure further provides a manufacturing method of the display device 100 and includes the following steps S1 to S4:

S1 is a step of providing the housing 10: providing the housing 10, wherein the housing 10 is substantially a rectangular parallelopiped and is disposed with the top surface 11, the bottom surface 12, and the two lateral surfaces 13.

S2 is a step of attaching the flexible display panel 21: attaching the flexible display panel 21 on the top surface 11 of the housing 10, and then attaching a lateral side of the flexible display screen 20 on the lateral surfaces 13 of the housing 10.

S3 is a step of attaching the first cover plate 22: attaching the first cover plate 22 on the top surface 11 of the housing 10, and then attaching a lateral side of the first cover plate 22 on the flexible display panel 21 located on the lateral surfaces 13 of the housing 10.

S4 is a step of attaching the second cover plate 23: attaching the second cover plate 23 on the top surface 11 of the housing 10, and then attaching a lateral side of the second cover plate 23 on the first cover plate 22 located on the lateral surfaces 13 of the housing 10.

Furthermore, two adjacent ones of the flexible display panel 21, the first cover plate 22, and the second cover plate 23 are connected to each other by the optically clear adhesive 30. The lateral surfaces 13 include the left side surface 131 and the right side surface 132, and the flexible display screen 20 covers the left side surface 131 and/or the right side surface 132 of the housing 10. Any one of the top surface 11 or the bottom surface 12 is set as an arc surface. At least one of the first cover plate 22 or the second cover plate 23 is a glass film with a thickness less than or equal to 150 μm. The glass film can ensure flatness and surface hardness of the flexible display screen 20, while tactile sense of the flexible display screen is consistent with a mobile device in the prior art. Furthermore, a material of the first cover plate 22 or the second cover plate 23 includes transparent polyimide.

Furthermore, the display device 100 further includes a third cover plate (not shown in the figures), and the third cover plate is disposed on the second cover plate 23. The disposing manner of the third cover plate is similar to that the first cover plate 22 disposed on the second cover plate 23, so redundant description will not be mentioned herein. A material of the third cover plate includes glass or transparent polyimide, that is, a layer number of cover plates of the display devices 100 is greater than or equal to 2. The display device 100 at least includes the first cover plate 22 and the second cover plate 23, and at the same time, more cover plates can be disposed, such as disposing the third cover plate, to improve hardness.

The beneficial effect of the present disclosure is: a display device 100 and a manufacturing method thereof are provided. Through covering the top surface 11, the bottom surface 12, and the lateral surfaces 13 by using one whole flexible display panel 21, this not only increases a screen-to-body ratio of the display device and realizes thinness, but also ensures that a surface of the flexible display panel 21 has a certain hardness and flatness.

### Second Embodiment

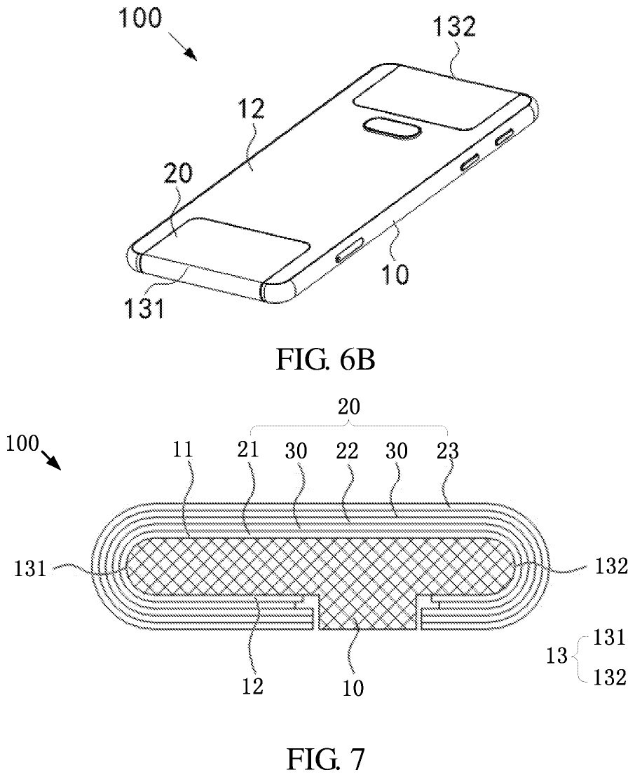

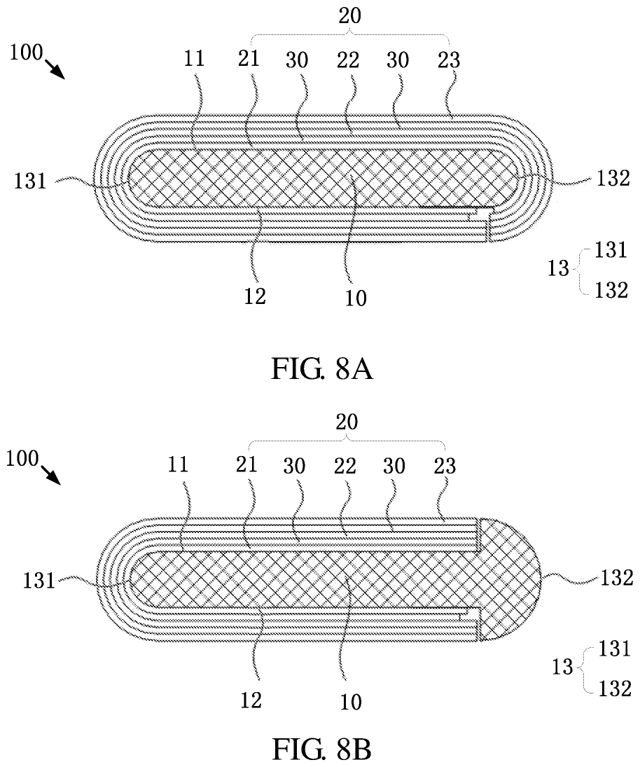

As illustrated in FIG. 6A, FIG. 6B, FIG. 7, FIG. 8A, and FIG. 8B, a second embodiment of the present disclosure provides a display device 100, which includes all technical features in the first embodiment. The difference between the first embodiment and the second embodiment is that the flexible display screen 20 of the second embodiment further covers the bottom surface 12 of the housing 10. A more specific covering manner includes two types: partially covering and completely covering. Illustrated in FIG. 6A, FIG. 6B, and FIG. 7 is the flexible display screen 20 partially covering the bottom surface 12 of the housing 10. Illustrated in FIG. 8A is the flexible display screen 20 completely covering the bottom surface 12, the left side surface 131, and the right side surface 132 of the housing 10. At this time, the flexible display screen 20 is a body which is independent and without physical partition, and aesthetic effect is better. Illustrated in FIG. 8B is the flexible display screen 20 completely covering the bottom surface 12 and left side surface 131 or right side surface 132 of the housing 10, that is, the flexible display screen 20 is in an U-shape, and at this time, only one of the lateral surfaces is a display region.

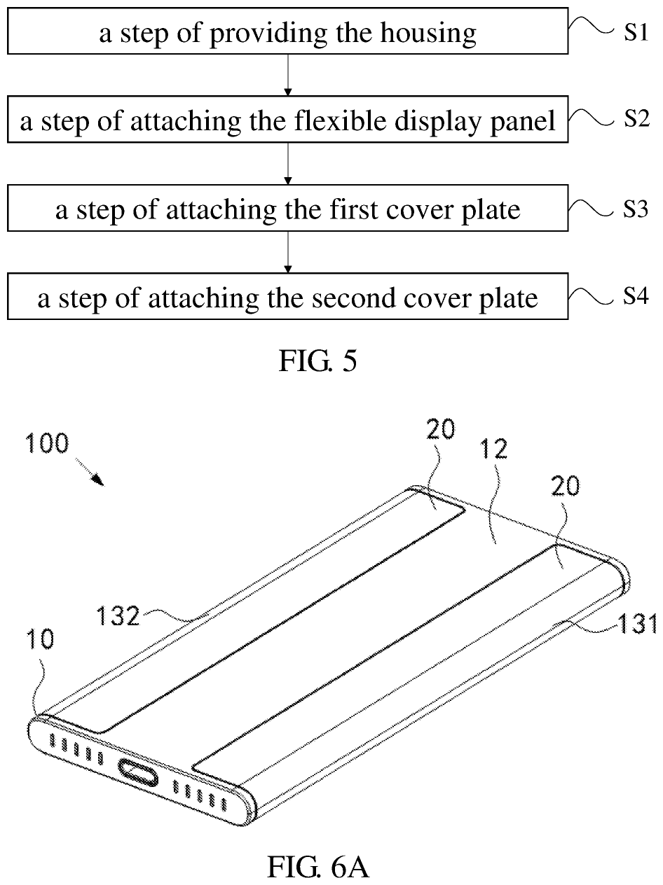

In the second embodiment, a manufacturing method of a display device 100 is further provided, which includes all technical features in the first embodiment. Please refer to FIG. 5, which includes steps S1 to S4 as follows. The difference between the first embodiment and the second embodiment is that in the manufacturing method of the second embodiment, a step of attaching the flexible display panel 21, the first cover plate 22, the second cover plate 23, which constitute the flexible display screen 20, on the bottom surface 12 of the housing 10 is further added.

Specifically, the step S2 of attaching the flexible display panel 21 further includes: attaching the flexible display panel 21 on the bottom surface 12 of the housing 10; the step S3 of attaching the first cover plate 22 further includes: attaching the first cover plate 22 on the flexible display panel 21 located on the bottom surface 12 of the housing 10; and the step S4 of attaching the second cover plate 23 further includes: attaching the second cover plate 23 on the first cover plate 22 located on the bottom surface 12 of the housing 10. Furthermore, two adjacent ones of the flexible display panel 21, the first cover plate 22, and the second cover plate 23 are bonded to be connected to each other by an optically clear adhesive 30.

The beneficial effect of the present disclosure is: a display device 100 and a manufacturing method thereof are provided. Through covering the top surface 11, the bottom surface 12, and the lateral surfaces 13 of the housing 10 by using one whole flexible display panel 21, this not only increases a screen-to-body ratio of the display device 100 and realizes thinness, but also ensures that a surface of the flexible display panel 21 has a certain hardness and flatness.

Mentioned above are preferred embodiments of the present disclosure. It should be noted that those skilled in the art, without departing from the technical theory of the present disclosure, can further make many changes and modifications, and the changes and the modifications should be considered within the scope of protection of the present disclosure.

1. A display device, comprising:
a housing, wherein the housing is substantially a rectangular parallelopiped and is disposed with a top surface, a bottom surface, and two lateral surfaces; and
a flexible display screen covering the top surface and the two lateral surfaces of the housing;
wherein the flexible display screen comprises:
a flexible display panel;
a first cover plate disposed on the flexible display panel; and
a second cover plate disposed on the first cover plate.

2. The display device as claimed in claim 1, wherein the two lateral surfaces comprise a left side surface and a right side surface, and the flexible display screen covers the left side surface and/or the right side surface of the housing.

3. The display device as claimed in claim 1, wherein the flexible display screen covers the bottom surface of the housing.

4. The display device as claimed in claim 4, wherein the flexible display screen completely covers the bottom surface of the housing.

5. The display device as claimed in claim 1, wherein any one of the top surface, the bottom surface, or the two lateral surfaces is disposed to be an arc surface.

6. The display device as claimed in claim 1, wherein at least one of the first cover plate or the second cover plate is a glass film with a thickness less than or equal to 150 μm.

7. The display device as claimed in claim 6, wherein a material of the first cover plate or the second cover plate comprises transparent polyimide.

8. (canceled)

9. A manufacturing method of a display device, comprising following steps:
providing a housing, wherein the housing is substantially a rectangular parallelopiped and is disposed with a top surface, a bottom surface, and two lateral surfaces;
attaching a flexible display panel on the top surface of the housing, and then attaching a lateral side of the flexible display screen on lateral surfaces of the housing;
attaching a first cover plate on the top surface of the housing, and then attaching a lateral side of the first cover plate on the flexible display panel located on the lateral surfaces of the housing; and
attaching a second cover plate on the top surface of the housing, and then attaching a lateral side of the second cover plate on the first cover plate located on the lateral surfaces of the housing.

10. The manufacturing method of the display device as claimed in claim 9, wherein
attaching the flexible display panel comprises: attaching the flexible display panel on the bottom surface of the housing;
attaching the first cover plate comprises: attaching the first cover plate on the flexible display panel located on the bottom surface of the housing; and
attaching the second cover plate comprises: attaching the second cover plate on the first cover plate located on the bottom surface of the housing.
